(19) United States
(12) Patent Application Publication
(10) Pub. No.: US 2024/0280895 A1
(43) Pub. Date: Aug. 22, 2024

(54) METHOD OF FABRICATING SEMICONDUCTOR DEVICE

(71) Applicant: SAMSUNG ELECTRONICS CO., LTD., Suwon-si (KR)

(72) Inventors: Jinnam YEEM, Suwon-si (KR); Hoin LEE, Suwon-si (KR); Dongkyun LEE, Suwon-si (KR); Sangchul YANG, Suwon-si (KR); Byung-Hyun LEE, Suwon-si (KR)

(21) Appl. No.: 18/381,773

(22) Filed: Oct. 19, 2023

(30) Foreign Application Priority Data
Feb. 17, 2023 (KR) 10-2023-0021565

(51) Int. Cl. G03F 1/70; H01L 21/027

(52) U.S. Cl. CPC G03F 1/70; H01L 21/027; H10B 12/315

(57) ABSTRACT

A method of fabricating a semiconductor device may include forming a target pattern on a first wafer by performing a first exposure process, measuring a misalignment value of the target pattern, calculating a block misalignment value and a pattern misalignment value based on the misalignment value, calculating a block correction value based on the block misalignment value and calculating a pattern correction value based on the pattern misalignment value, and performing a second exposure process on a second wafer, based on the block correction value and the pattern correction value.

### CROSS-REFERENCE TO RELATED APPLICATIONS

This U.S. non-provisional patent application claims priority under 35 U.S.C. § 119 to Korean Patent Application No. 10-2023-0021565, filed on Feb. 17, 2023, in the Korean Intellectual Property Office, the entire contents of which are hereby incorporated by reference.

### BACKGROUND

### 1. Field

The present disclosure relates to a method of fabricating a semiconductor device, and in particular, to a method of correcting an exposure process, based on a block correction value, when a semiconductor device is fabricated.

### 2. Description of the Related Art

Due to their small-size, multifunctionality, and/or low-cost characteristics, semiconductor devices are being touted as important elements in the electronics industry. Semiconductor devices may be classified into semiconductor memory devices for storing data, semiconductor logic devices for processing data, and a hybrid semiconductor device that includes both memory devices and logic elements.

With the recent trend of high speed and low power consumption in electronic devices, semiconductor devices in the electronic devices are also required to have high operating speeds and/or low operating voltages. In order to satisfy this requirement, it is desirable to increase an integration density of semiconductor devices. However, as the integration density of semiconductor devices increases, semiconductor devices may experience deterioration in electrical characteristics and production yield. Accordingly, many studies are being conducted to improve the electrical characteristics and production yield of semiconductor devices.

### SUMMARY

Embodiments may be directed to a method of fabricating a semiconductor device, including forming a target pattern on a first wafer by performing a first exposure process, measuring a misalignment value of the target pattern, calculating a block misalignment value and a pattern misalignment value based on the misalignment value, calculating a block correction value based on the block misalignment value, calculating a pattern correction value based on the pattern misalignment value, and performing a second exposure process on a second wafer, based on the block correction value and the pattern correction value.

Embodiments may further provide a method of fabricating a semiconductor device including forming target patterns on a first block region and a second block region of a first wafer by performing a first exposure process, measuring a misalignment value of the target patterns, calculating a first block misalignment value of the first block region and a second block misalignment value of the second block region, based on the misalignment value, calculating a first block correction value based on the first block misalignment value, calculating a second block correction value based on the second block misalignment value, performing a correction step corresponding to the first block region of the first exposure process, based on the first block correction value, and performing a correction step corresponding to the second block region of the first exposure process, based on the second block correction value.

Embodiments may further include a method of fabricating a semiconductor device including forming a target pattern on a first wafer by performing a first exposure process, measuring a misalignment value of the target pattern, calculating a block misalignment value and a pattern misalignment value based on the block misalignment value, calculating a block misalignment average value based on the block misalignment value, calculating a block correction value based on the block misalignment average value and calculating a pattern correction value based on the pattern misalignment value, correcting the first exposure process based on the block correction value and the pattern correction value, and performing a second exposure process on a second wafer, based on the corrected first exposure process.

### BRIEF DESCRIPTION OF THE DRAWINGS

Features will become apparent to those of skill in the art by describing in detail exemplary embodiments with reference to the attached drawings in which:

FIG. 1 is a plan view illustrating shot regions of a wafer.

FIG. 2 is a plan view illustrating chip regions of a shot region.

FIG. 3 is a plan view illustrating bank regions of a chip region.

FIG. 4 is a plan view illustrating block regions of a bank region.

FIG. 5 is a plan view illustrating misalignment of target patterns of a block region.

FIG. 6 is a flow chart of a method of fabricating a semiconductor device, according to an embodiment.

FIG. 7 is a table showing an x-axis block misalignment average value, an x-axis block correction value, and an x-axis block estimation value.

FIG. 8 is a table showing a y-axis block misalignment average value, a y-axis block correction value, and a y-axis block estimation value.

FIG. 9 is a flow chart illustrating a method of fabricating a semiconductor device, according to an embodiment.

FIG. 10A is a plan view illustrating a semiconductor device according to an embodiment.

FIG. 10B is a sectional view taken along a line A-A′ of FIG. 10A.

### DETAILED DESCRIPTION

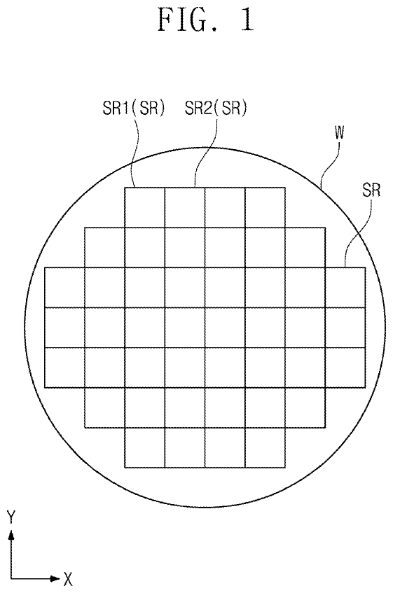

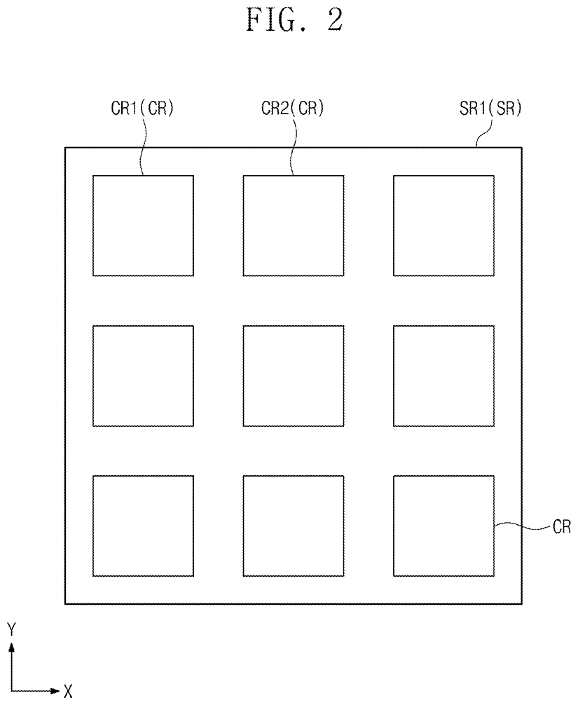

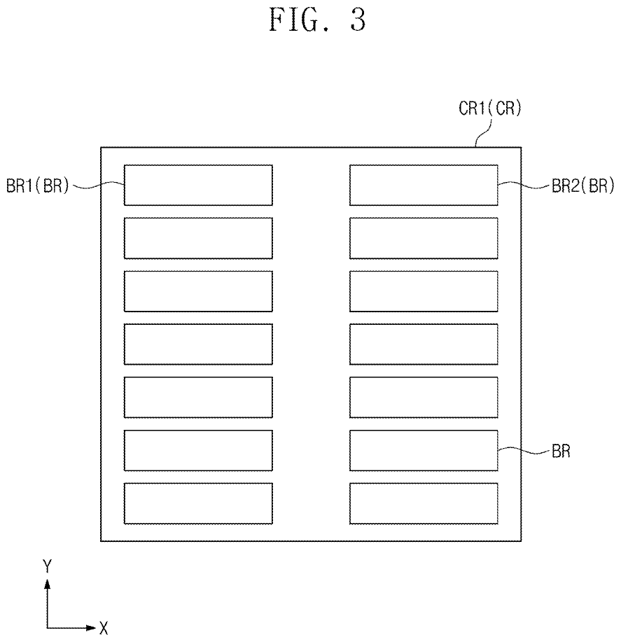

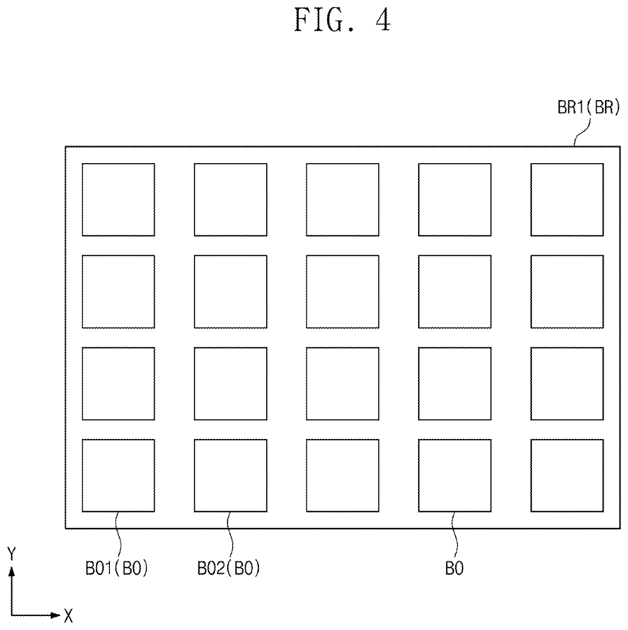

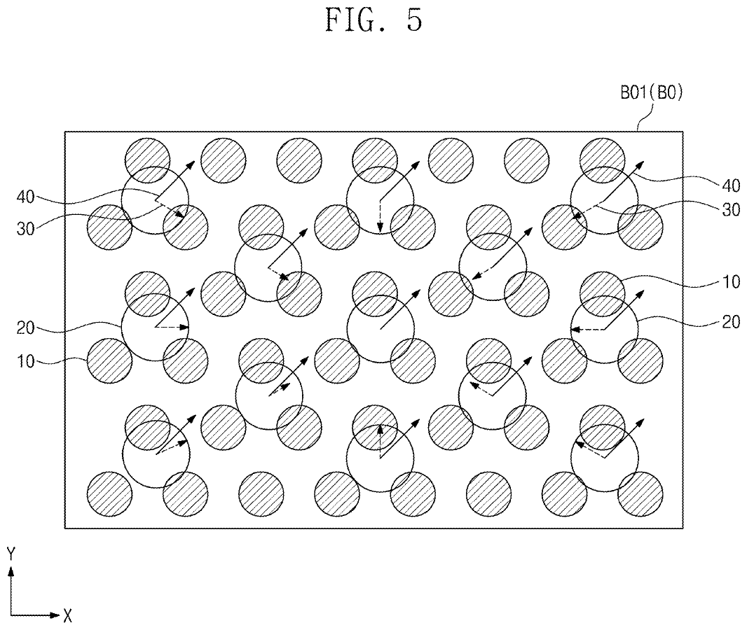

FIG. 1 is a plan view illustrating shot regions of a wafer. FIG. 2 is a plan view illustrating chip regions of a shot region. FIG. 3 is a plan view illustrating bank regions of a chip region. FIG. 4 is a plan view illustrating block regions of a bank region, and FIG. 5 is a plan view illustrating a misalignment of target patterns of a block region.

Referring to FIGS. 1 to 5, a wafer W may include a plurality of shot regions SR. The shot regions SR may be separate regions that are arranged along x- and y-axes. The number of the shot regions SR that are included in each wafer W may not be limited to what is shown in the illustrated example.

In an embodiment, the shot regions SR may undergo an exposure process using varying process conditions such as focus values or dose values. For example, a first shot region SR1 and a second shot region SR2 that are adjacent to each other may undergo exposure processes that are performed with focus values or dose values that are different from each other.

Each of the shot regions SR may include a plurality of chip regions CR. For example, the first shot region SR1 may include a plurality of chip regions CR. The number of the chip regions CR in each shot region SR may not be limited to what is shown in the illustrated example.

In an embodiment, a scribe region may be provided between the chip regions CR. For example, the scribe region may be provided between a first chip region CR1 and a second chip region CR2.

Each of the chip regions CR may include a plurality of bank regions BR. For example, the first chip region CR1 may include a plurality of bank regions BR. The number of the bank regions BR in each chip region CR may not be limited to what is shown in the illustrated example.

In an embodiment, a peripheral region for a peripheral circuit may be provided between the bank regions BR, which are spaced apart from each other in a direction of an x-axis. For example, the peripheral region may be provided between a first bank region BR1 and a second bank region BR2.

Each of the bank regions BR may include a plurality of block regions BO. For example, the first bank region BR1 may include a plurality of block regions BO. The number of the block regions BO in each bank region BR may not be limited to what is shown in the illustrated example.

In an embodiment, a memory cell structure or a logic cell structure may be disposed on each of the block regions BO.

Base patterns 10 and target patterns 20 may be disposed on each of the block regions BO. For example, the base patterns 10 and the target patterns 20 may be disposed on a first block region BO1. The sizes and the arrangement of the base and target patterns 10 and 20 may not be limited to what is shown in the illustrated example.

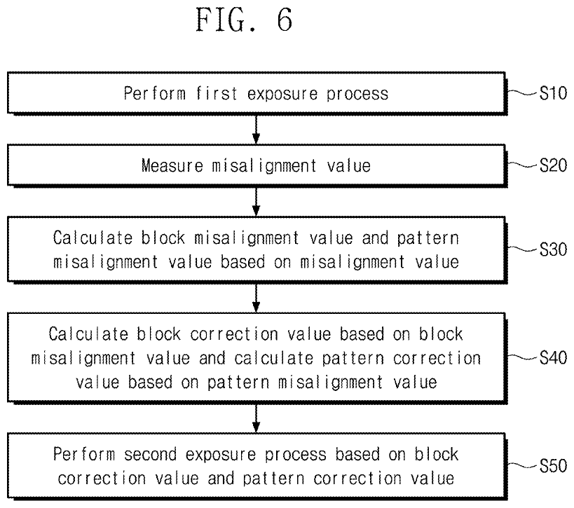

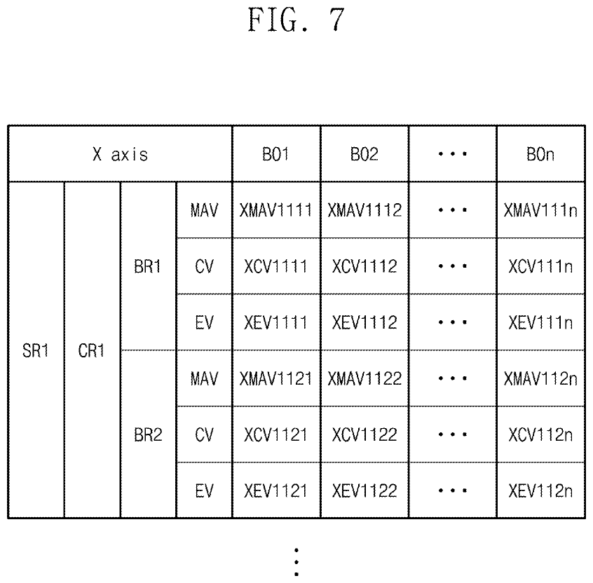

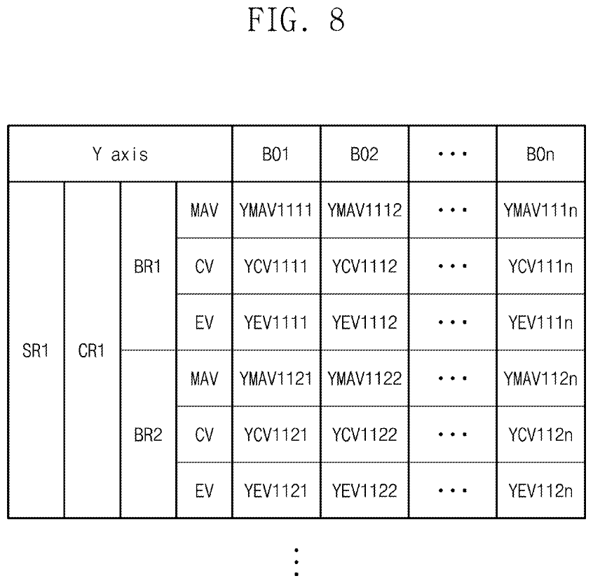

FIG. 6 is a flow chart of a method of fabricating a semiconductor device, according to an embodiment. FIG. 7 is a table showing an x-axis block misalignment average value, an x-axis block correction value, and an x-axis block estimation value. FIG. 8 is a table showing a y-axis block misalignment average value, a y-axis block correction value, and a y-axis block estimation value.

Referring to FIG. 6, the fabrication method may include performing a first exposure process (in S10), measuring a misalignment value (in S20), calculating a block misalignment value and a pattern misalignment value based on the misalignment value (in S30), calculating a block correction value based on the block misalignment value and calculating a pattern correction value based on the pattern misalignment value (in S40), and performing a second exposure process based on the block correction value and the pattern correction value (in S50).

Referring to FIGS. 1 to 6, the fabrication method may include forming the base patterns 10 on the block regions BO of the first wafer W. Thereafter, the first exposure process may be performed to form the target patterns 20 on the block regions BO of the first wafer W (in S10).

In an embodiment, the formation of the target patterns 20 may include forming a mask layer on the base patterns 10, forming a photoresist layer on the mask layer, performing the first exposure process on the photoresist layer, developing the photoresist layer to form a photoresist pattern, and etching the mask layer using the photoresist pattern as an etch mask.

In certain cases, the target patterns 20 may be misaligned from desired positions. The misalignment of the target pattern 20 may depend on positions of the shot region SR, the chip region CR, the bank region BR, and the block region BO, in which the target pattern 20 is disposed, as well as a position of the target pattern 20 in the block region BO.

Misalignment values of the target patterns 20 may be measured (in S20). Block misalignment values and pattern misalignment values of the target patterns 20 may be calculated based on the misalignment values of the target patterns 20 (in S30).

The block misalignment value may be a value that is obtained by calculating the degree of misalignment of the target pattern 20, based on the positions of the shot region SR, the chip region CR, the bank region BR, and the block region BO, in which the target pattern 20 is disposed. The pattern misalignment value may be a value that is obtained by calculating the degree of misalignment of the target pattern 20, based on the position of the target pattern 20 in the block region BO. The block misalignment value and the target misalignment value may be calculated in a mutually-dependent manner.

Each of the target patterns 20 may have a block misalignment value and a pattern misalignment value. The block misalignment value and the pattern misalignment value of each of the target patterns 20 may be calculated based on the misalignment values of the target patterns 20.

Referring to FIG. 5, a block misalignment vector 40 and a pattern misalignment vector 30 of the target pattern 20 are illustrated. For convenience in description, the misalignment vectors 30 and 40 are illustrated to be larger than the pattern misalignment value and the block misalignment value. Since, as shown, the target patterns 20 in a first block region BO1 are disposed in the same shot region SR, the same chip region CR, the same bank region BR, and the same block region BO, the block misalignment vectors 40 of the target patterns 20 in the first block region BO1 may be similar to each other.

Referring to FIGS. 1 to 6, block correction values of the block regions BO may be calculated based on the block misalignment values of the target patterns 20, and pattern correction values of the target patterns 20 may be calculated based on the pattern misalignment values of the target patterns 20 (in S40). The block correction value and the pattern correction value may be used to correct the misalignment of the target pattern 20.

Block misalignment average values of the block regions BO may be calculated based on the block misalignment values of the target patterns 20. The block misalignment average value may be a mean value of the block misalignment values of the target patterns 20 disposed in the block region BO. For example, the block misalignment average value of the first block region BO1 may be a mean value of the block misalignment values of the target patterns 20 disposed in the first block region BO1. Each block misalignment average value may be calculated on each block region BO. The block correction values of the block regions BO may be calculated based on the block misalignment average values of the block regions BO.

In an embodiment, the calculation of the block correction values of the block regions BO may include obtaining optimized block correction values for the block regions BO through a machine learning process on the block misalignment average values of the block regions BO.

In an embodiment, the calculation of the block correction values of the block regions BO may include obtaining a fitting function through a data fitting process on the block misalignment average values of the block regions BO and obtaining optimized block correction values for the block regions BO using the fitting function.

In an embodiment, the calculation of the pattern correction values of the target patterns 20 may include obtaining optimized pattern correction values for the target patterns 20 through a machine learning process on the pattern misalignment values of the target patterns 20.

Different ones of the block regions BO may have block correction values different from each other. For example, a block correction value of a first block region BO1 may be different from a block correction value of a second block region BO2. For example, the block correction value of the block region BO that is disposed outside the bank region BR may be greater than the block correction value of the block region BO that is disposed inside the bank region BR.

Different target patterns 20 that are disposed in one block region BO may have pattern correction values that are different from each other. For example, the pattern correction value of the target pattern 20 that is disposed outside the first block region BO1 may be different from the pattern correction value of the target pattern 20 that is disposed inside the first block region BO1.

One block region BO may include one set of pattern correction values. The set of pattern correction values may include the pattern correction values of the target patterns 20 included in one block region BO.

Different ones of the block regions BO may have the same set of pattern correction values. For example, pattern correction values that are included in a first set of pattern correction values for the first block region BO1 may be equal to pattern correction values that are included in a second set of pattern correction values for the second block region BO2.

The target patterns 20, which are disposed at corresponding positions in different block regions BO, may have the same pattern correction values. For example, the target pattern 20 of the first block region BO1 and the target pattern 20 of the second block region BO2, which is disposed at a position corresponding to the target pattern 20 of the first block region BO1, may have the same pattern correction values.

The first exposure process may be corrected based on the block correction values and the pattern correction values, and the second exposure process may be performed on a second wafer, based on the corrected first exposure process (in S50). Before performing the second exposure process, base patterns may be formed on the second wafer. The first exposure process may be corrected in units of the block region BO by the block correction value.

In an embodiment, the performing of the second exposure process based on the block correction value and the pattern correction value may include correcting a layout for the first exposure process, based on the block correction value and the pattern correction value, manufacturing a photomask based on the corrected layout, and performing the second exposure process using the manufactured photomask.

In an embodiment, the performing of the second exposure process based on the block correction value and the pattern correction value may include correcting an exposure method for the first exposure process based on the block correction value and the pattern correction value and performing the second exposure process based on the corrected exposure method.

Correction corresponding to each of the block regions BO of the first exposure process may be performed based on each of the block correction values. For example, the correction corresponding to the first block region BO1 of the first exposure process may be performed based on a block correction value of the first block region BO1, and the correction corresponding to the second block region BO2 of the first exposure process may be performed based on a block correction value of the second block region BO2.

In the correction of the first exposure process, the correction for all of the target patterns 20 that are disposed in one block region BO may be performed using one block correction value. For example, in the correction of the first exposure process, all of the target patterns 20 that are disposed in the first block region BO1 may be corrected to the block correction value of the first block region BO1.

In the correction of the first exposure process, the correction corresponding to each of the target patterns 20 may be performed based on each of the pattern correction values. Since the pattern correction values, which are included in the first set of pattern correction values for the first block region BO1, are equal to the pattern correction values, which are included in the second set of pattern correction values for the second block region BO2, the correction corresponding to the target patterns 20 of the first block region BO1 based on the pattern correction values may be the same as the correction corresponding to the target patterns 20 of the second block region BO2 based on the pattern correction values.

As a result of the second exposure process on the second wafer, the target patterns may be formed on the second wafer. Since the first exposure process is corrected using the block correction value and the pattern correction value, a misalignment may be corrected in units of a block, and the misalignment of target patterns formed on the second wafer may be minimized.

Referring to FIGS. 7 and 8, a block misalignment average value MAV may include x-axis block misalignment average values XMAV1111, XMAV1112, XMAV111n, XMAV1121, XMAV1122, and XMAV112n and y-axis block misalignment average values YMAV1111, YMAV1112, YMAV111n, YMAV1121, YMAV1122, and YMAV112n. For example, the first block region BO1 of the first bank region BR1 of the first chip region CR1 of the first shot region SR1 may include the x-axis block misalignment average value XMAV1111 and the y-axis block misalignment average value YMAV1111.

A block correction value CV may include x-axis block correction values XCV1111, XCV1112, XCV111n, XCV1121, XCV1122, and XCV112n and y-axis block correction values YCV1111, YCV1112, YCV111n, YCV1121, YCV1122, and YCV112n. For example, the first block region BO1 of the first bank region BR1 of the first chip region CR1 of the first shot region SR1 may include an x-axis block correction value XCV1111 and a y-axis block correction value YCV1111.

The x-axis block correction values XCV1111, XCV1112, XCV111n, XCV1121, XCV1122, and XCV112n may be calculated based on the x-axis block misalignment average values XMAV1111, XMAV1112, XMAV111n, XMAV1121, XMAV1122, and XMAV112n. For example, in the case where the x-axis block misalignment average value XMAV1111 of the first block region BO1 of the first bank region BR1 of the first chip region CR1 of the first shot region SR1 is positive, the x-axis block correction value XCV1111 of the first block region BO1 of the first bank region BR1 of the first chip region CR1 of the first shot region SR1 may be calculated as a negative value to compensate for this.

The y-axis block correction values YCV1111, YCV1112, YCV111n, YCV1121, YCV1122, and YCV112n may be calculated based on the y-axis block misalignment average values YMAV1111, YMAV1112, YMAV111n, YMAV1121, YMAV1122, and YMAV112n. For example, in the case where the y-axis block misalignment average value YMAV1111 of the first block region BO1 of the first bank region BR1 of the first chip region CR1 of the first shot region SR1 is positive, the y-axis block correction value YCV1111 of the first block region BO1 of the first bank region BR1 of the first chip region CR1 of the first shot region SR1 may be calculated as a negative value to compensate for this.

Block estimation values EV can be calculated based on the block misalignment average values MAV and the block correction values CV. The block estimation values EV may represent misalignment values, which are predicted after the correction of the exposure process using the block correction values CV.

The block estimation values EV may include x-axis block estimation values XEV1111, XEV1112, XEV111n, XEV1121, XEV1122, and XEV112n and y-axis block estimation values YEV1111, YEV1112, YEV111n, YEV1121, YEV1122, and YEV112n.

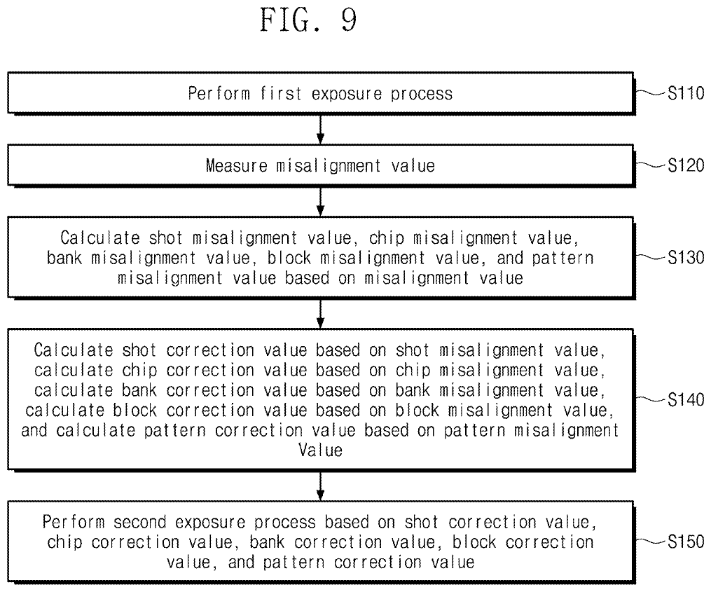

FIG. 9 is a flow chart illustrating a method of fabricating a semiconductor device, according to an embodiment.

Referring to FIG. 9, the fabrication method may include performing a first exposure process (in S110), measuring a misalignment value (in S120), calculating a shot misalignment value, a chip misalignment value, a bank misalignment value, a block misalignment value, and a pattern misalignment value based on the misalignment value (in S130), calculating a shot correction value based on the shot misalignment value, calculating a chip correction value based on the chip misalignment value, calculating a bank correction value based on the bank misalignment value, calculating a block correction value based on the block misalignment value, calculating a pattern correction value based on the pattern misalignment value (in S140), and performing the second exposure process based on the shot correction value, the chip correction value, the bank correction value, the block correction value, and the pattern correction value (in S150).

Referring to FIGS. 1 to 5 and 9, the fabrication method may include forming the base patterns 10 on the block regions BO of the first wafer W. Thereafter, the first exposure process may be performed to form the target patterns 20 on the block regions BO of the first wafer W (in S110).

The misalignment values of the target patterns 20 may be measured (in S120). The shot misalignment values, the chip misalignment values, the bank misalignment values, the block misalignment values, and the pattern misalignment values of the target patterns 20 may be calculated based on the misalignment values of the target patterns 20 (in S130).

The shot misalignment value may be a value that is obtained by calculating the degree of misalignment of the target pattern 20 using the position of the shot region SR provided with the target pattern 20. The chip misalignment value may be a value that is obtained by calculating the degree of misalignment of the target pattern 20 using the position of the chip region CR provided with the target pattern 20. The bank misalignment value is a value that may be obtained by calculating the degree of misalignment of the target pattern 20 using the position of the bank region BR provided with the target pattern 20. The block misalignment value is a value that may be obtained by calculating the degree of misalignment of the target pattern 20 using the position of the block region BO provided with the target pattern 20.

Shot misalignment average values may be calculated based on the shot misalignment values and shot correction values of the shot regions SR, which may be calculated based on the shot misalignment average values. Chip misalignment average values may be calculated based on the chip misalignment values. Chip correction values of the chip regions CR may be calculated based on the chip misalignment average values. Bank misalignment average values may be calculated based on the bank misalignment values, and bank correction values of the bank regions BR may be calculated based on the bank misalignment average values. Block misalignment average values may be calculated based on the block misalignment values, and the block correction values of the block regions BO may be calculated based on the block misalignment average values. The pattern correction values of the target patterns 20 may be calculated based on the pattern misalignment values (in S140).

Different ones of the shot regions SR may have shot correction values different from each other, and different ones of the chip regions CR may have chip correction values that are different from each other. Different ones of the bank regions BR may have bank correction values that are different from each other. Different ones of the block regions BO may have block correction values that are different from each other. Different ones of the block regions BO may have the same set of pattern correction values.

The first exposure process may be corrected based on the shot correction values, the chip correction values, the bank correction values, the block correction values, and the pattern correction values. The second exposure process may be performed on the second wafer, based on the corrected first exposure process (in S150).

The first exposure process may be corrected in units of the shot region SR by the shot correction value, may be corrected in units of the chip region CR by the chip correction value, may be corrected in units of the bank region BR by the bank correction value, and may be corrected in units of the block region BO by the block correction value.

In the fabrication method according to an embodiment, the exposure process may be corrected using at least one of the shot correction value, the chip correction value, the bank correction value, and the block correction value.

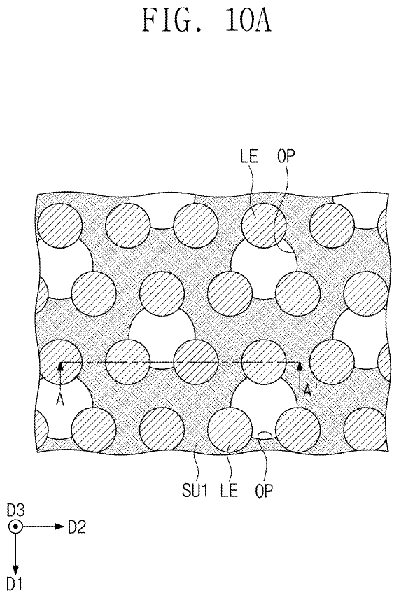

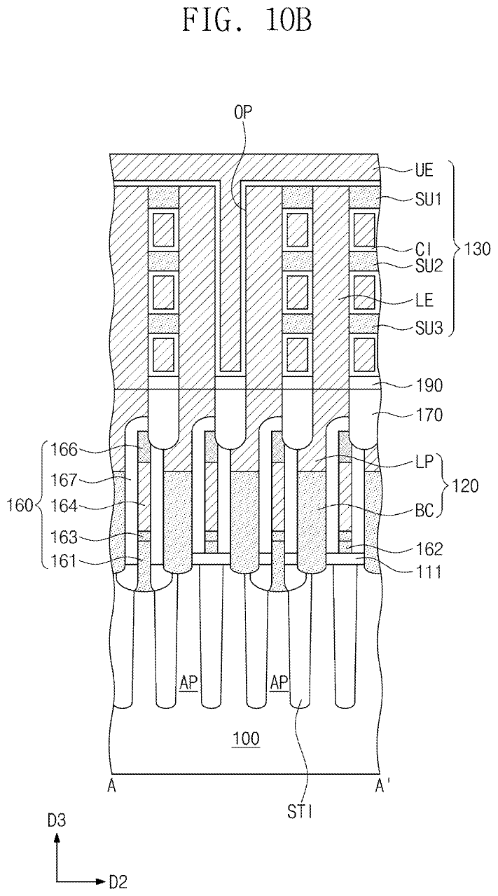

FIG. 10A is a plan view illustrating a semiconductor device according to an embodiment. FIG. 10B is a sectional view taken along a line A-A′ of FIG. 10A.

Referring to FIGS. 10A and 10B, a memory cell structure may be disposed in the block region of the semiconductor device. The memory cell structure may include a substrate 100. In an embodiment, the substrate 100 may be a semiconductor substrate. As examples, the substrate 100 may be formed of or include silicon, germanium, silicon-germanium, GaP, or GaAs. In an embodiment, the substrate 100 may include a silicon-on-insulator (SOI) substrate or a germanium-on-insulator (GOI) substrate. The substrate 100 may have a plate shape that is extended in a first direction D1 and a second direction D2. The first and second directions D1 and D2 may cross each other. As an example, the first and second directions D1 and D2 may be horizontal directions that are orthogonal to each other.

The substrate 100 may include active patterns AP. The active patterns AP may be upper portions of the substrate 100 protruding in a third direction D3. The active patterns AP may be spaced apart from each other. The third direction D3 may cross the first and second directions D1 and D2. As an example, the third direction D3 may be a vertical direction that is orthogonal to the first and second directions D1 and D2.

A device isolation layer STI may be provided in a space provided between the active patterns AP. The device isolation layer STI may be provided in the substrate 100. The active patterns AP may be defined by the device isolation layer STI. Each of the active patterns AP may be enclosed by the device isolation layer STI. The device isolation layer STI may include an insulating material. As an example, the device isolation layer STI may be formed of or include an oxide material.

Gate structures (not shown) may extend in the second direction D2. The gate structures may be arranged in the first direction D1. The gate structure may be a buried gate structure, which is buried in the active patterns AP and the device isolation layer STI. The gate structure and the active pattern AP may constitute a cell transistor.

Insulating patterns 111 may be provided on the device isolation layer STI. The insulating pattern 111 may include an insulating material. In an embodiment, the insulating pattern 111 may include a plurality of insulating layers.

Bit line structures 160 may extend in the first direction D1. The bit line structures 160 may be arranged in the second direction D2. The bit line structure 160 may be formed on the insulating pattern 111 and the active pattern AP. The bit line structure 160 may be electrically connected to the active pattern AP.

Each of the bit line structures 160 may include bit line contacts 161, first conductive layers 162, a second conductive layer 163, a third conductive layer 164, a bit line capping layer 166, and a bit line spacer 167.

The bit line contacts 161 of the bit line structure 160 may be arranged in the first direction D1. The first conductive layers 162 of the bit line structure 160 may be arranged in the first direction D1. The bit line contacts 161 and the first conductive layers 162 of the bit line structure 160 may be alternately disposed in the first direction D1. The bit line contact 161 may be disposed on the active pattern AP. The bit line contact 161 may penetrate the insulating pattern 111. The first conductive layer 162 may be provided on the insulating pattern 111. The bit line contact 161 and the first conductive layer 162 may include at least one of conductive materials. As an example, the bit line contact 161 and the first conductive layer 162 may be formed of or include poly silicon. In an embodiment, the bit line contacts 161 and the first conductive layers 162, which are included in one bit line structure 160, may be connected to each other without an interface, thereby forming a single object.

The second conductive layer 163 may be provided on the bit line contacts 161 and the first conductive layers 162. The third conductive layer 164 may be provided on the second conductive layer 163. The bit line capping layer 166 may be provided on the third conductive layer 164. The second conductive layer 163 and the third conductive layer 164 may include at least one of conductive materials. As an example, the second conductive layer 163 may be formed of or include poly silicon, and the third conductive layer 164 may be formed of or include a metallic material. The bit line capping layer 166 may include an insulating material. As an example, the bit line capping layer 166 may be formed of or include a nitride material. In an embodiment, the number of the conductive layer, that are included in one bit line structure 160 may be greater or less than what is shown in the illustrated example.

The bit line spacer 167 may cover top and side surfaces of the bit line capping layer 166, side surfaces of the first to third conductive layers 162, 163, and 164, and side surfaces of the bit line contacts 161. The bit line spacer 167 may include an insulating material. In an embodiment, the bit line spacer 167 may include a plurality of insulating layers.

A capacitor contact structure 120 that is electrically connected to the active pattern AP of the substrate 100 may be provided. The capacitor contact structure 120 may include a storage node contact BC and a landing pad LP.

The storage node contact BC may be provided on the active pattern AP. The storage node contact BC may be provided between the bit line structures 160, which are adjacent to each other. The storage node contact BC may be provided on a side surface of the bit line structure 160. The storage node contact BC may include a conductive material. As an example, the storage node contact BC may be formed of or include poly silicon.

Landing pads LP may be provided. The landing pads LP may be provided on the storage node contacts BC. The landing pads LP may include a conductive material. As an example, the landing pads LP may be formed of or include at least one of metallic materials. In an embodiment, a metal silicide layer and a barrier layer may be provided between the storage node contacts BC and the landing pads LP.

A filling pattern 170 may be provided to separate the landing pads LP from each other. The filling pattern 170 may enclose the landing pads LP. The filling pattern 170 may include an insulating material.

An etch stop layer 190 may be provided on the filling pattern 170. The etch stop layer 190 may include an insulating material.

A capacitor structure 130 may be provided. The capacitor structure 130 may include lower electrodes LE, a first supporter SU1, a second supporter SU2, a third supporter SU3, a capacitor insulating layer CI, and an upper electrode UE. The lower electrodes LE may be pillar-shaped patterns that extend in the third direction D3. The first to third supporters SU1, SU2, and SU3 may support the lower electrodes LE.

Openings OP may be provided to penetrate the first to third supporters SU1, SU2, and SU3. A portion of the capacitor insulating layer CI and a portion of the upper electrode UE may be provided in the opening OP.

The openings OP may be formed by the method described with reference to FIG. 6 or 9. In an embodiment, the openings OP may be formed through an exposure process that is corrected based on the block correction value and the pattern correction value. Since the correction is performed on each block based on the block correction value, it may be possible to minimize any misalignment issue between the lower electrodes LE and the openings OP.

When the misalignment issue between the lower electrodes LE and the openings OP is minimized, it may be possible to suppress a misalignment caused by the bending of the lower electrodes LE, and to prevent an insufficient deposition issue of the upper electrode UE, which could be caused when there is a misalignment issue, and to mitigate the concentration of an electric field, which could be caused when a sharp portion exists in one of the structures.

In a method of fabricating a semiconductor device according to an embodiment, by correcting an exposure process in units of a block using a block correction value, it may be possible to minimize a misalignment issue and provide a method of fabricating a semiconductor device with improved electrical and reliability characteristics.

While example embodiments have been particularly shown and described, it will be understood by one of ordinary skill in the art that variations in form and detail may be made therein without departing from the spirit and scope of the attached claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of fabricating a semiconductor device, comprising:
forming a target pattern on a first wafer by performing a first exposure process;
measuring a misalignment value of the target pattern;
calculating a block misalignment value and a pattern misalignment value based on the misalignment value;
calculating a block correction value based on the block misalignment value, calculating a pattern correction value based on the pattern misalignment value, and
performing a second exposure process on a second wafer, based on the block correction value and the pattern correction value.

2. The method as claimed in claim 1, wherein forming the target pattern includes:
forming a photoresist layer;
performing the first exposure process on the photoresist layer to form a photoresist pattern; and
forming the target pattern using the photoresist pattern.

3. The method as claimed in claim 1, wherein performing the second exposure process includes:
correcting a layout of the first exposure process based on the block correction value and the pattern correction value; and
performing the second exposure process based on the corrected layout.

4. The method as claimed in claim 1, wherein performing the second exposure process includes:
correcting an exposure method for the first exposure process, based on the block correction value and the pattern correction value; and
performing the second exposure process based on the corrected exposure method.

5. The method as claimed in claim 1, wherein:
the first wafer includes a first block region and a second block region, and
the calculating of the block correction value includes calculating a first block correction value of the first block region and a second block correction value of the second block region.

6. The method as claimed in claim 5, wherein the calculating of the first block correction value and the second block correction value further includes calculating a first block misalignment average value of the first block region and a second misalignment average value of the second block region, based on the block misalignment value.

7. The method as claimed in claim 6, wherein the calculating of the first block correction value and the second block correction value further includes calculating the first block correction value based on the first block misalignment average value and calculating the second block correction value based on the second block misalignment average value.

8. The method as claimed in claim 5, wherein the performing of the second exposure process includes:
performing a correction step corresponding to the first block region of the first exposure process, based on the first block correction value; and
performing a correction step corresponding to the second block region of the first exposure process, based on the second block correction value.

9. The method as claimed in claim 5, wherein:
the first block region includes a first pattern correction value set,
the second block region includes a second pattern correction value set, and
the pattern correction value of the first pattern correction value set is equal to the pattern correction value of the second pattern correction value set.

10. A method of fabricating a semiconductor device, comprising:
forming target patterns on a first block region and a second block region of a first wafer by performing a first exposure process;
measuring a misalignment value of the target patterns;
calculating a first block misalignment value of the first block region and a second block misalignment value of the second block region, based on the misalignment value;
calculating a first block correction value based on the first block misalignment value,
calculating a second block correction value based on the second block misalignment value;
performing a correction step corresponding to the first block region of the first exposure process, based on the first block correction value, and
performing a correction step corresponding to the second block region of the first exposure process, based on the second block correction value.

11. The method as claimed in claim 10, further comprising:
calculating a pattern misalignment value based on the misalignment value; and
calculating a pattern correction value based on the pattern misalignment value.

12. The method as claimed in claim 10, wherein the first block region includes a first pattern correction value set,
the second block region includes a second pattern correction value set, and
the pattern correction value of the first pattern correction value set is equal to the pattern correction value of the second pattern correction value set.

13. The method as claimed in claim 10, further comprising:
calculating a bank misalignment value based on the misalignment value;
calculating a bank correction value based on the bank misalignment value; and
correcting the first exposure process based on the bank correction value.

14. The method as claimed in claim 10, further comprising:
calculating a chip misalignment value based on the misalignment value;
calculating a chip correction value based on the chip misalignment value; and
correcting the first exposure process based on the chip correction value.

15. The method as claimed in claim 10, further comprising:
calculating a shot misalignment value based on the misalignment value;
calculating a shot correction value based on the shot misalignment value; and
correcting the first exposure process based on the shot correction value.

16. The method as claimed in claim 10, further comprising performing a second exposure process on a second wafer, based on the corrected first exposure process.

17. The method as claimed in claim 10, wherein the first block correction value includes an x-axis block correction value and a y-axis block correction value.

18. The method as claimed in claim 17, wherein:
the first block misalignment value includes an x-axis block misalignment value and a y-axis block misalignment value, and
the calculating of the first block correction value includes:
calculating the x-axis block correction value based on the x-axis block misalignment value; and
calculating the y-axis block correction value based on the y-axis block misalignment value.

19. A method of fabricating a semiconductor device, comprising:
forming a target pattern on a first wafer by performing a first exposure process;
measuring a misalignment value of the target pattern;
calculating a block misalignment value and a pattern misalignment value based on the misalignment value;
calculating a block misalignment average value based on the block misalignment value;
calculating a block correction value based on the block misalignment average value and calculating a pattern correction value based on the pattern misalignment value;
correcting the first exposure process based on the block correction value and the pattern correction value; and
performing a second exposure process on a second wafer, based on the corrected first exposure process.

20. The method as claimed in claim 19, wherein the first exposure process is corrected in units of a block region by the block correction value.
